(19) United States
(12) Patent Application Publication
(10) Pub. No.: US 2015/0027755 A1
(43) Pub. Date: Jan. 29, 2015

(54) TRANSPARENT CONDUCTIVE FILM, SUBSTRATE CARRYING TRANSPARENT CONDUCTIVE FILM, AND PRODUCTION METHOD THEREOF

(71) Applicants: Akira Tsujimoto, Nara (JP); Akihiko Tadamasa, Osaka (JP); Taisuke Matsui, Osaka (JP); Eri Yasuhara, Osaka (JP)

(72) Inventors: Akira Tsujimoto, Nara (JP); Akihiko Tadamasa, Osaka (JP); Taisuke Matsui, Osaka (JP); Eri Yasuhara, Osaka (JP)

(73) Assignee: Panasonic Corporation, Osaka (JP)

(21) Appl. No.: 14/006,568

(22) PCT Filed: Dec. 11, 2012
(86) PCT No.: PCT/JP2012/082084

§ 371 Date: Sep. 20, 2013

(30) Foreign Application Priority Data
Dec. 19, 2011 (JP) 2011-276893

(51) Int. Cl. H05K 1/02; H05K 3/46; H05K 3/02; H05K 1/03; H05K 1/09

(52) U.S. Cl. CPC H05K 1/0274; H05K 1/0313; H05K 1/097; H05K 3/027; H05K 3/4664; H05K 2201/032; H05K 2201/2054
USPC 174/253; 427/553; 427/108

(57) ABSTRACT

Provided is a transparent conductive film wherein an electrically conductive region is converted to an electrically insulating region more readily and rapidly than traditional conductive films and the level difference between the electrically conductive region and the electrically insulating region is smaller. The transparent conductive film has an electrically conductive region 4 and an electrically insulating region 5. The electrically conductive region 4 contains a resin component 10, a metal nanowire 2 and an insulation-promoting component 3. The insulation-promoting component 3 has a light absorption higher than that of the metal nanowire 2. The electrically insulating region 5 is defined by a region which contains a resin component 10 but not the metal nanowire 2 or a region which contains a resin component 10 and additionally a metal nanowire 2 having an aspect ratio of smaller than that of the metal nanowire 2.

### TECHNICAL FIELD

The present invention relates to a transparent conductive film for use in various devices including touch panels, a substrate carrying the transparent conductive film, and a production method thereof.

### BACKGROUND ART

Transparent conductive films have been used widely in touch panels, organic EL devices, liquid crystal displays, solar cells, and other devices. For example, an ITO film as transparent conductive film is formed by sputtering on the surface of a transparent substrate, and transparent electrodes are produced by patterning (pattern formation) on the ITO film by photoetching. In addition as shown in FIG. 3A, a transparent conductive film 1 containing metal nanowires 2 is formed on the surface of a transparent substrate 9, and the undesirable regions thereof are removed by photoetching or laser beam machining, to produce transparent electrodes constituted by the preserved electrically conductive regions 4, as shown in FIG. 3B. Further, as shown in FIG. 3B, only electrically conductive regions 4 serving as transparent electrodes are formed directly on the surface of the transparent substrate 9 by a printing process such as gravure or screen printing.

However, such methods may cause a level difference corresponding to the film thickness of the electrically conductive regions 4 with regard to the surface of a transparent substrate 9, as indicated by the two-direction arrow in FIG. 3B. In other words, the surface of the electrically conductive region 4 serving as the transparent electrode is not flush with the surface of the region of the transparent substrate 9 (electrically insulating regions 5) where the electrically conductive regions 4 are not formed. Thus, the level difference causes exposure of the electrically conductive regions 4 when a device containing such electrically conductive regions is used in touch panels, and causes a short circuit or generation of leak current between the electrically conductive regions 4 and other electrodes (not shown in the Figure) when it is used in organic EL devices.

Thus there has been proposed making the surface of the electrically conductive regions 4 flush with the surface of electrically insulating regions 5 (see, for example, Patent Document 1). The method for producing a conductive nanofiber sheet described in Patent Document 1 includes the steps of forming a patterned conductive layer containing conductive nanofibers over a substrate sheet to make the entire surface thereof conductive; and converting part of the patterned conductive layer into a patterned insulating layer by irradiating, with a high-energy ray, the part of the patterned conductive layer formed to thermally fuse and break the conductive nanofibers.

### PRIOR ART DOCUMENTS

### Patent Literature

Patent Document 1: JP 2010-140859 A

### SUMMARY OF THE INVENTION

### Problems to be Resolved by the Invention

However, the method described in Patent Document 1, which fuses and breaks the conductive nanofibers thermally by direct irradiation of the conductive nanofibers with the high-energy ray, needs more time to prepare the patterned insulating layer and causes an increase in energy consumption for preparation of the insulation pattern layer. In addition, the method described in Patent Document 1 is not suited for preparation of large-area conductive nanofiber sheets, as it demands a longer period for preparation of the insulation pattern layer.

An object of the present invention, which was made under the circumstances above, is to provide a transparent conductive film which enables easy and rapid conversion of an electrically conductive region into an electrically insulating region and has a smaller level difference between the electrically conductive region and the electrically insulating region, a substrate carrying the transparent conductive film, and a production method thereof.

### Means of Solving the Problems

The transparent conductive film according to the present invention includes: an electrically conductive region; and an electrically insulating region. The electrically conductive region contains a resin component, a metal nanowire, and an insulator-conversion promoting component. The insulator-conversion promoting component is a nanoparticle having a light absorption higher than that of the metal nanowire. The electrically insulating region is defined by a region which contains a resin component but not the metal nanowire or a region which contains a resin component and additionally a metal nanowire having an aspect ratio of smaller than that of the metal nanowire.

The transparent conductive film according to the present invention includes: an electrically conductive region; and an electrically insulating region. The electrically conductive region contains a resin component, a metal nanowire, and an insulator-conversion promoting component. The insulator-conversion promoting component is a photochemical or thermal acid generator. The electrically insulating region is defined by a region which contains a resin component but not the metal nanowire or a region which contains a resin component and additionally a metal nanowire having an aspect ratio of smaller than that of the metal nanowire.

Preferably in the transparent conductive film, the insulator-conversion promoting component is a component that decomposes the metal nanowire or reduces the aspect ratio of the metal nanowire when irradiated with light or heated.

The transparent conductive film according to the present invention includes: an electrically conductive region; and an electrically insulating region. The electrically conductive region contains a resin component, a metal nanowire and an insulator-conversion promoting component. The insulator-conversion promoting component is defined to decompose the metal nanowire or reduces the aspect ratio of the metal nanowire when irradiated with light or heated. The electrically insulating region is defined by a region which contains a resin component but not the metal nanowire or a region which contains a resin component and additionally a metal nanowire having an aspect ratio of smaller than that of the metal nanowire.

Preferably in the transparent conductive film, the insulator-conversion promoting component is a metal nanoparticle.

Preferably in the transparent conductive film, the insulator-conversion promoting component is carbon.

Preferably in the transparent conductive film, the insulator-conversion promoting component is a metal nanoparticle deposited on a surface of the metal nanowire through electroless plating.

Preferably in the transparent conductive film, the metal nanoparticle is an Ag nanoparticle.

Preferably in the transparent conductive film, the insulator-conversion promoting component has a refractive index-adjusting function of increasing or decreasing refractive indices of the electrically conductive region and the electrically insulating region.

Preferably in the transparent conductive film, the electrically conductive region and the electrically insulating region contain refractive index-adjusting components increasing or decreasing the refractive indices of the electrically conductive region and the electrically insulating region, respectively.

Preferably in the transparent conductive film, the metal nanowire is an Ag nanowire.

Preferably in the transparent conductive film, the metal nanowire has an average diameter of 100 nm or less.

The substrate carrying the transparent conductive film according to the present invention is characterized by being prepared by forming the transparent conductive film on a transparent substrate.

The production method for the substrate carrying a transparent conductive film according to the present invention includes the steps of forming a transparent conductive film on a transparent substrate, the transparent conductive film being constituted by an electrically conductive region containing a resin component, a metal nanowire, and an insulator-conversion promoting component, and the insulator-conversion promoting component being defined by a nanoparticle having light absorption higher than that of the metal nanowire; and forming an electrically insulating region by irradiating a region to be insulated of the transparent conductive film with light.

The production method for the substrate carrying a transparent conductive film according to the present invention includes the steps of forming a transparent conductive film on a transparent substrate, the transparent conductive film being constituted by an electrically conductive region containing a resin component, a metal nanowire and an insulator-conversion promoting component, and the insulator-conversion promoting component being defined by a photochemical or thermal acid generator; and forming an electrically insulating region by irradiating with light or heating a region to be insulated of the transparent conductive film.

### Advantageous Effects of Invention

According to the present invention, when irradiated with light or heated, the insulator-conversion promoting component decomposes metal nanowires or reduces the aspect ratio of the metal nanowires, thereby reducing the number of contact points between metal nanowires. Thus, it is possible to convert the electrically conductive regions into the electrically insulating regions more readily and rapidly than before and decrease the level difference between the electrically conductive region and the electrically insulating region.

### BRIEF DESCRIPTION OF DRAWINGS

FIG. 1A is a schematic cross-sectional view illustrating a transparent conductive film before insulation with regard to an example in an embodiment of the present invention;

FIG. 1B is a schematic cross-sectional view illustrating the transparent conductive film after insulation with regard to an example in an embodiment of the present invention;

FIG. 1C is a schematic cross-sectional view illustrating the transparent conductive film after insulation with regard to an example in an embodiment of the present invention;

FIG. 2 is a schematic view illustrating an insulator-conversion promoting component integrated with metal nanowires;

FIG. 3A is a schematic cross-sectional view illustrating a transparent conductive film of the prior art before insulation; and

FIG. 3B is a schematic cross-sectional view illustrating a transparent conductive film of the prior art after insulation.

### DESCRIPTION OF EMBODIMENTS

The following explanations are made to embodiments in accordance with the present invention.

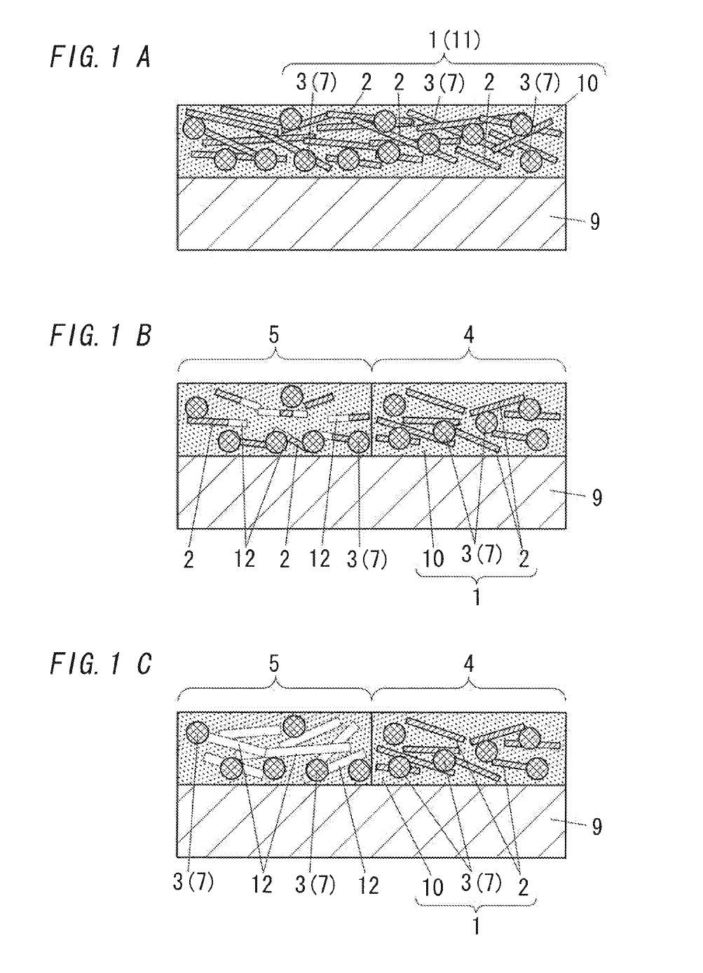

FIG. 1 is a cross-sectional view illustrating an instance of a substrate carrying a transparent conductive film that is prepared by forming (directly or indirectly) a transparent conductive film 1 according to the present invention on the surface of a transparent substrate 9. The transparent conductive film 1 can be prepared, as shown in FIG. 1A, by applying a transparent conductive material 11 on the surface of the transparent substrate 9 and drying it under heat. The transparent conductive material 11 contains metal nanowires 2 and binder materials. The binder materials include an insulator-conversion promoting component 3, a resin component 10 and a solvent. As will be described in detail below, the insulator-conversion promoting component 3 can show its function of converting the electrically conductive regions 4 into the electrically insulating regions 5 (non-conductive regions) when the regions to be converted into an insulator of the transparent conductive film 1 are irradiated with light or heated. Thus, the insulator-conversion promoting component 3 serves as a component having a function of promoting conversion to an insulator by reducing the number of contact points between the metal nanowires 2 by reducing the aspect ratio of the metal nanowires 2, as shown in FIG. 1B or by decomposing the metal nanowires 2, as shown in FIG. 1C. Meanwhile, the regions not irradiated with light or heated remain as the electrically conductive regions 4. It is thus possible to perform patterning (pattern formation) on the electrically conductive regions 4 by forming the electrically insulating regions 5 into a particular shape by irradiation with light or heating. In FIGS. 1B and 1C, the transparent conductive film 1 has the electrically conductive region 4 and the electrically insulating region 5 separately formed.

The metal nanowires 2 used are arbitrary and the production method for the metal nanowires 2 is not particularly limited. Thus, the metal nanowires 2 can be prepared by any known means including liquid- and gas-phase methods. Its specific production method is also not particularly limited, and any known production method may be used. The production methods for Ag nanowires (silver nanowires) are described, for example, in Adv. Mater. 2002, 14, pp 833-837 and Chem. Mater. 2002, 14, pp 4736-4745 and JP 2009-505358 A; Au nanowires (gold nanowires) in JP 2006-233252 A; Cu nanowires (copper nanowires) in JP 2002-266007 A; and Co nanowires (cobalt nanowires) in JP 2004-149871 A. In particular, the production methods for Ag nanowires described in Adv. Mater. and Chem. Mater. permit production of nanowires in aqueous medium readily in a larger amount and silver is a metal that has the highest conductivity in metals. Thus, it is possible to employ these methods favorably as the production methods for the metal nanowire 2 for use in the present invention. Accordingly, the metal nanowires 2 are preferably Ag nanowires. It is possible in this way to make the conductivity of the transparent conductive film 1 (in electrically conductive regions 4) higher than that obtained when other metal nanowires 2 are used.

In addition, the metal nanowires 2 preferably have an average diameter of 100 nm or less from the viewpoint of transparency and preferably of 10 nm or more from the viewpoint of conductivity. An average diameter of 100 nm or less is desirable for suppressing reduction of light transmittance. It is possible to make the metal nanowires express the function as conductor effectively at an average diameter of 10 nm or more and thus, an average diameter larger than the average diameter is desirable for improvement of conductivity. Thus, the average diameter is more preferably 20 to 100 nm, most preferably 40 to 100 nm. In addition, the metal nanowires 2 preferably have an average length of 1 μm or more from the viewpoint of conductivity and 100 μm or less for prevention of adverse effects on transparency by aggregation. The average length is more preferably 1 to 50 μm, most preferably 3 to 50 μm. The average diameter and length of the metal nanowires 2 can be determined as the arithmetic means of the measurement values obtained by taking electron micrographs of the sufficient number of metal nanowires 2 under SEM or TEM and measuring the diameter and the length of the images of individual metal nanowires 2. The length of a metal nanowire 2 should be determined as it is stretched but, as the metal nanowire 2 is often bent actually, the length is determined by measuring the projected diameter and area of the metal nanowire 2 from the electron micrograph by using an image-analyzing instrument, assuming that the metal nanowire has a cylindrical shape (length=projected area/projected diameter). The number of metal nanowires 2 to be measured is preferably at least 100, and it is more preferable to measure 300 or more metal nanowires 2.

The insulator-conversion promoting component 3 is a component having a function of decomposing the metal nanowires 2 present in the vicinity of the insulator-conversion promoting component 3 when irradiated with light or heated, or at least reducing the aspect ratio (average length/average diameter) of the metal nanowire 2 if it cannot decompose them completely.

Such an insulator-conversion promoting component 3 is preferably a nanoparticle having a light absorption higher than that of the metal nanowire 2. Examples of the nanoparticle include nanoparticles of carbon, antimony-containing tin oxide (ATO), titanium oxide, zirconium oxide, alumina (Al₂O₃), Ag, Cu, Fe, Sn, Ni, Zr and the like. The average particle diameter of the nanoparticle is preferably 3 to 200 nm, more preferably 5 to 100 nm. The average particle diameter can be determined by a laser diffraction-scattering method. In a case where the insulator-conversion promoting component 3 is the nanoparticle described above, the nanoparticle can decompose the metal nanowire 2 or reduce the aspect ratio of the metal nanowire 2 because the nanoparticle preferentially absorbs light during irradiation with light.

The light absorption, as used herein, is an indicator of the absorption efficiency of the light used in patterning. The light absorption depends on the material, surface color, particle diameter and others of the substance irradiated with light. The insulator-conversion promoting component 3 higher in light absorption than the metal nanowire 2 is more inclined to preferentially absorb the light used in irradiation and convert it into heat, and is thus effective in decomposing the metal nanowires 2 or reducing the aspect ratio of the metal nanowires 2. The light absorption of the insulator-conversion promoting component 3 relative to the metal nanowire 2 can be evaluated preferably with the light from the light source used during patterning. For example, such evaluation can be performed by use of a light source that emits light having a relatively wide wavelength range including the absorption wavelength of the metal nanowire 2. When the evaluation using such a light source is performed on the light absorption of the insulator-conversion promoting component 3 that has the light absorption higher than that of the metal nanowires 2, the insulator-conversion promoting component 3 shows the higher light absorption relative to the metal nanowire 2, provided that a light source emitting light having a wavelength range corresponding to the absorption wavelength range of the insulator-conversion promoting component 3 is used. Specifically, the light absorption is evaluated, for example, as described below. First, a first film and a second film are formed separately for example on the transparent substrate 9. The first film contains the metal nanowires 2 and the resin component 10, but does not contain the insulator-conversion promoting components 3, while the second film contains the insulator-conversion promoting components 3 and the resin component 10, but does not contain the metal nanowires 2. In addition, the content of the metal nanowires 2 in the first film is equivalent to the content of the insulator-conversion promoting components 3 in the second film. Next, the total light transmittances of the first and second films are determined on a haze meter. If the total light transmittance of the second film is lower than that of the first film, the insulator-conversion promoting component 3 probably has higher light absorption. On the contrary if the total light transmittance of the first film is lower than that of the second film, the metal nanowire 2 probably has higher light absorption. A light source D65 showing emission characteristics in a wider wavelength range of about 300 to 800 nm can be used as the light source of the haze meter.

The insulator-conversion promoting component 3 is preferably a metal nanoparticle 7. The metal nanoparticle 7 preferably has an average particle diameter of 3 to 200 nm, more preferably 5 to 100 nm. When the insulator-conversion promoting component 3 is not a nonmetal nanoparticle but the metal nanoparticle 7, the insulator-conversion promoting component 3 present in the electrically conductive region 4 cooperates with the metal nanowire 2 to cause an increase in the conductivity of this electrically conductive region 4.

The insulator-conversion promoting component 3 is preferably carbon. The carbons include, for example, carbon particles, graphite, carbon nanotubes, graphenes, and the like and the shape thereof is not particularly limited. The average particle diameter and the aspect ratio of the carbon are also not particularly limited, but the average particle diameter or the average diameter is preferably 3 to 200 nm, more preferably 5 to 100 nm from the viewpoint of transparency. Since carbon is black in color, it can absorb light preferentially during irradiation with light. In addition since carbon is conductive, the insulator-conversion promoting component 3 present in the electrically conductive region 4 cooperates with the metal nanowire 2 to cause an increase in the conductivity of this electrically conductive region 4.

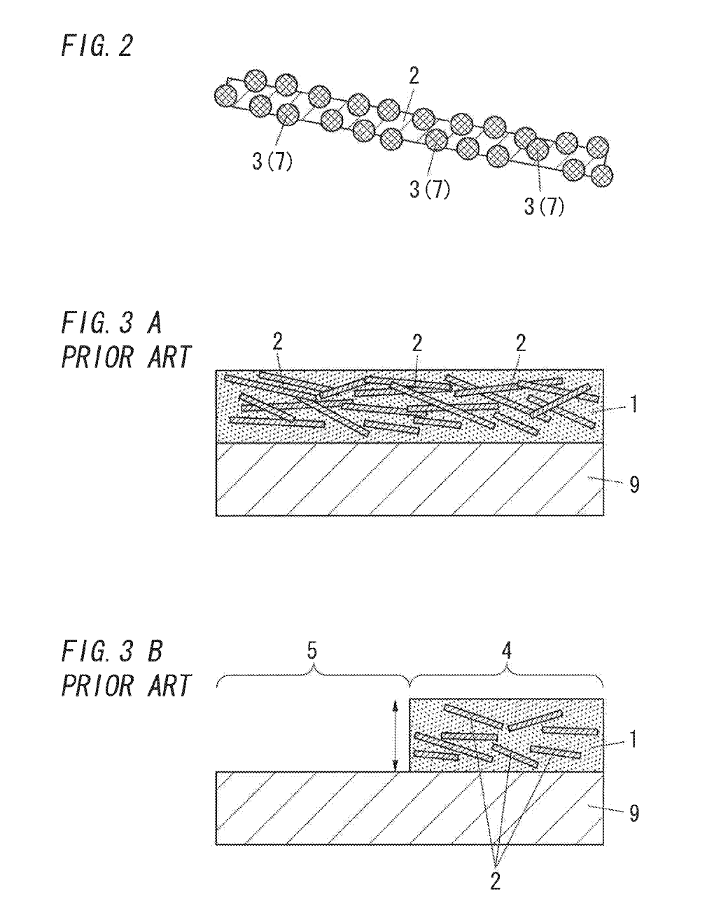

It is also preferable that the insulator-conversion promoting component 3 is the metal nanoparticle 7 deposited on the surface of the metal nanowire 2 through electroless plating, as shown in FIG. 2. The insulator-conversion promoting component 3 can be obtained by the process including the steps of; dispersing the metal nanowires 2 in a plating solution containing ions of the metal to be deposited; and adding a reducing agent thereto. The metals to be deposited include, for example, Ag, Ni, Cr and the like. The metal nanoparticle 7 deposited preferably has an average particle diameter of 0.5 to 100 nm, more preferably 1 to 50 nm. In such a case, as the metal nanowire 2 and the metal nanoparticle 7 are integrated with each other, the metal nanoparticle 7 decomposes the metal nanowire 2 or reduces the aspect ratio of the metal nanowire 2 immediately when irradiated with light or heated. As described above when the metal nanowire 2 and the metal nanoparticle 7 are integrated with each other, the binder material may not contain an additional insulator-conversion promoting component 3 because the metal nanoparticle 7 serves as the insulator-conversion promoting component 3.

The metal nanoparticle 7 is preferably an Ag nanoparticle (silver nanoparticle). It is possible in this way to make the light absorption and the conductivity higher than those obtained when other metal nanoparticles 7 are used. In particular, the combination of Ag nanowire and Ag nanoparticle is preferable. In this case, since the Ag nanowire larger in size is more whitish in color and the Ag nanoparticle smaller in size is more blackish, the Ag nanoparticle can absorb light preferentially during irradiation with light. Further, since the Ag nanowire and the Ag nanoparticle are both made of Ag, they can make the film more conductive, compared to nanowires and nanoparticles of other metals.

The insulator-conversion promoting component 3 is preferably a photochemical or thermal acid generator. The photochemical acid generator is a compound generating an acid as it is irradiated with light, while the thermal acid generator is a compound generating an acid as it is heated. Examples of the photochemical and thermal acid generators for use include aromatic sulfonium salts, diazo disulfonated compounds, phenyliodonium salts and the like. In particular, the photochemical acid generator for use is, for example, a benzoin derivative. When the insulator-conversion promoting component 3 is a photochemical or thermal acid generator, the acid generated therefrom when the insulator-conversion promoting component 3 is irradiated with light or heated dissolves the metal nanowires 2. Hence, it is possible to facilitate decomposition of the metal nanowires 2 or reduction of the aspect ratio of the metal nanowires 2.

The insulator-conversion promoting component 3 may have a refractive index-adjusting function of increasing or decreasing the refractive index of the electrically conductive region 4 and the electrically insulating region 5. The insulator-conversion promoting components 3 increasing the refractive index are, for example, nanoparticles of titanium oxide, zirconium oxide, alumina (Al₂O₃) and the like. The insulator-conversion promoting components 3 decreasing the refractive index are, for example, nanoparticles of silicon dioxide (SiO₂) and the like. The insulator-conversion promoting component 3 having such a refractive index-adjusting function may be either solid particles, hollow particles or porous particles and may have a spherical or any other shape. It is possible with such an insulator-conversion promoting component 3 having a refractive index-adjusting function to easily adjust the refractive index of the transparent conductive film 1, for example by improving the light output efficiency therefrom.

The resin components 10 are, for example, cellulosic resins, silicone resins, fluoroplastics, acrylic resins, polyethylene resins, polypropylene resins, polyethylene terephthalate resins, polymethyl methacrylate resins, polystyrene resins, polyethersulfone resins, polyarylate resins, polycarbonate resins, polyurethane resins, polyacrylonitrile resins, polyvinylacetal resins, polyamide resins, polyimide resins, diacrylic phthalate resins, polyvinyl chloride resins, polyvinylidene chloride resins, polyvinyl acetate resins, other thermoplastic resins, copolymers of the two or more monomers constituting these resins, and the like.

The solvents for use include, for example, alcohols such as methanol, ethanol, and isopropyl alcohol (IPA); ketones such as methylethyl ketone, methyl isobutyl ketone, and cyclohexanone; esters such as ethyl acetate and butyl acetate; halogenated hydrocarbons; aromatic hydrocarbons such as toluene and xylene; and the mixtures thereof. In addition to the organic solvents above, water and also a combination of water and an organic solvent may also be used. The amount of the solvent is suitably adjusted to such a concentration that: the solid matters can be dissolved or dispersed uniformly; the binder material or the transparent conductive material 11 produced is resistant to aggregation during storage; and the transparent conductive material 11 is not excessively diluted when it is applied to the transparent substrate 9. It is preferable to prepare a binder material or a transparent conductive material 11 at high concentration, as the amount of the solvent used is reduced in the range satisfying the conditions above, store it in the state demanding smaller volume, and dilute the concentrated solution to a concentration suitable for coating before use. When the total amount of the solid matter and the solvent is 100 parts by mass, it is preferable to use the solvent in an amount of 50 to 99.9 parts by mass with respect to 0.1 to 50 parts by mass of the total solid, more preferably in an amount of 70 to 99.5 parts by mass with respect to 0.5 to 30 wt parts solvent of the total solid. It is possible in this way to obtain a binder material or a transparent conductive material 11 superior especially in dispersion stability and thus suited for long-term storage.

It is possible to prepare a binder material by blending the insulator-conversion promoting component 3, the resin component 10, and the solvent described above. A refractive index-adjusting component may be added then. The refractive index-adjusting component is a compound increasing or decreasing the refractive indices of the electrically conductive region 4 and the electrically insulating region 5 of the transparent conductive film 1. Examples thereof include magnesium fluoride, calcium fluoride, cerium fluoride, aluminum fluoride, acrylic particles, styrene particles, urethane particles, styrene acrylic particles and the crosslinked particles thereof, melamine-formalin condensate particles, fluorine-containing polymer particles such as PTFE (polytetrafluoroethylene) particles, PFA (perfluoroalkoxy resin) particles, FEP (tetrafluoroethylene-hexafluoropropylene copolymer) particles, PVD F (polyfluorovinylidene) particles, and ETFE (ethylene-tetrafluoroethylene copolymer) particles, silicone resin particles, glass beads and the like. Such a refractive index-adjusting component may be either solid particles, hollow particles or porous particles and may have a spherical or other shape. When such a refractive index-adjusting component is contained in the electrically conductive region 4 and the electrically insulating region 5, even if the insulator-conversion promoting component 3 does not have a refractive index-adjusting function, it is possible to adjust easily the refractive index of the transparent conductive film 1, for example, by improving the light output efficiency thereof.

Next, it is possible then to prepare a transparent conductive material 11 by blending metal nanowires 2 and a binder material. The amount of the metal nanowires 2 blended in the transparent conductive material 11 is preferably adjusted so that the metal nanowires 2 are contained in an amount of 0.01 to 90 mass % in the transparent conductive film 1 after the transparent conductive film 1 is formed. The content of the metal nanowires 2 is more preferably 0.1 to 30 mass %, most preferably, 0.5 to 10 mass %. When the composite of the metal nanowires 2 and the metal nanoparticles 7, as shown in FIG. 2, is used as the insulator-conversion promoting component 3, this insulator-conversion promoting component 3 may be added during not the process of producing the binder material but the process of producing the transparent conductive material 11.

The transparent substrate 9 for use may be any substrate, e.g., a rigid transparent glass plate such as of non-alkali glass or soda-lime glass or a flexible transparent plastic plate such as of a polycarbonate resin or a polyethylene terephthalate (PET) resin. The transparent substrate 9 may be in the shape, for example, of flat plate, sheet, film or the like. The raw materials for the transparent substrate 9 include, for example in addition to the inorganic materials described above, quartz, silicon and the like. Organic materials other than those described above include, for example, acetate resins such as triacetyl cellulose (TAC), polyester resins, polyethersulfone resins, polysulfone resins, polyamide resins, polyimide resins, polyolefin resins, acrylic resins, polynorbornene resins, cellulosic resins, polyarylate resins, polystyrene resins, polyvinyl alcohol resins, polyvinyl chloride resins, polyvinylidene chloride resins, polyacrylic resins and the like.

The transparent conductive film 1 according to the present invention can be prepared in the following manner. As shown in FIG. 1A, the transparent conductive material 11 is applied on the surface of the transparent substrate 9 and is dried and cured under heat for example under the condition of 20 to 150° C. for 0.5 to 60 minutes, to give the transparent conductive film 1. Examples of the methods of applying the transparent conductive material 11 include spin coating method, die coating method, casting method, spray coating method, gravure coating method, roll coating method, flow coating method, printing method, dip coating method, slide coating method, casting method, bar coating method, meniscus coater method, bead coater method, screen printing method, gravure printing method, flexographic printing method and the like. The transparent conductive film 1 thus formed contains the metal nanowires 2, the insulator-conversion promoting components 3 and others, as they are uniformly dispersed. The transparent conductive film 1 preferably has a film thickness for example of 30 to 300 nm, more preferably 60 to 150 nm. The surface of the transparent conductive film 1 may be pressed for surface smoothening and for stabilization of resistance, for example, using a press, a roll press or a roller after preparation of the transparent conductive film 1.

Next, when the insulator-conversion promoting component 3 that functions when irradiated with light is used, only the region of the transparent conductive film 1 to be converted into an insulator (left half of FIGS. 1B and 1C) is irradiated with light, while the region not to be converted into an insulator (right half of FIGS. 1B and 1C) is covered with a mask and kept not exposed to light. The light source used then may be, for example, a gas laser such as argon or xenon laser, a solid-state laser such as UV-YAG or YAG laser, or the light from an ultraviolet lamp such as xenon lamp, xenon flash lamp, high-pressure mercury lamp, low-pressure mercury lamp, excimer lamp or deuterium lamp, but it is not limited to the light sources above, provided that the light source can emit light having a wavelength range permitting absorption by the insulator-conversion promoting component 3. For example, the wavelength of the light for irradiation is 250 to 400 nm. Since it is sufficient that light is provided to at least the insulator-conversion promoting component 3 and is absorbed by it, there is no need to irradiate directly the metal nanowire 2 with light to decompose it. Hence, not strong light but weak light is sufficient and an energy density of light, for example, ranges from 0.1 to 3 J/cm², and preferably ranges from about 0.2 to 1.5 J/cm². The insulator-conversion promoting component 3 present in the region irradiated with light decomposes the metal nanowire 2 present in the vicinity of the insulator-conversion promoting component 3 (FIG. 1C) or, if it cannot decompose it completely, reduces the aspect ratio of the metal nanowire 2 (FIG. 1B), thus decreasing the number of contact points between the metal nanowires 2. It is possible in this way to convert the region that exists as the electrically conductive region 4 before irradiation with light into the electrically insulating region 5 after irradiation with light more readily and easily than before. In addition, since the light supplied may be light that is weak enough not to decompose the resin component 10, the electrically insulating region 5 retains a film thickness similar to that of the electrically conductive region 4. Hence, it is possible to reduce the level difference between the electrically conductive region 4 and the electrically insulating region 5. There are voids 12 formed in the electrically insulating region 5 at the positions where the metal nanowires 2 are decomposed, but these voids 12 do not cause any problem particularly.

Alternatively, when the insulator-conversion promoting component 3 showing its function when heated is used, only the region of the transparent conductive film 1 to be converted into an insulator (left half of FIGS. 1B and 1C) is heated, while the region not to be converted into an insulator (right half of FIGS. 1B and 1C) is left unheated. The heating method used then is not limited and may be, for example, a method of using a heat press, heat stamp, heat roll or heater that is designed to heat only the regions to be converted into an insulator or a method of spraying hot air or gas on the transparent conductive film as the regions uninsulated are covered with a heat-insulating mask. Since the region to be converted into an insulator need not be removed completely by heating, the heating condition is preferably 150 to 300° C. for 1 to 180 seconds, more preferably 160 to 250° C. for 3 to 90 seconds. The insulator-conversion promoting component 3 present in the heated region decomposes the metal nanowires 2 present in the vicinity of the insulator-conversion promoting component 3 (FIG. 1C) or, if it cannot decompose them completely, reduces the aspect ratio of the metal nanowires 2 (FIG. 1B), reducing the number of contact points between the metal nanowires 2. It is possible in this way to convert the region that serves as the electrically conductive regions 4 before heating into the electrically insulating region 5 after heating more readily and rapidly than before. In addition, as the heating condition is milder, the electrically insulating region 5 retain a film thickness similar to that of the electrically conductive region 4 and the level difference between the electrically conductive region 4 and the electrically insulating region 5 is kept smaller. There are voids 12 formed in the electrically insulating region 5 at the positions where the metal nanowires 2 are decomposed, but these voids 12 do not cause any problem particularly.

It is possible in the manner described above to prepare a substrate carrying the transparent conductive film, as shown in FIGS. 1B and 1C. The substrate carrying the transparent conductive film includes the transparent conductive film 1 that includes the electrically conductive region 4 and the electrically insulating region 5 and is formed on the surface of the transparent substrate 9. The electrically conductive region 4 contains the metal nanowires 2 and the insulator-conversion promoting component 3. Meanwhile, the electrically insulating region 5 contains no metal nanowire 2 (FIG. 1C) or contain the metal nanowires 2 having an aspect ratio smaller than that of the standard metal nanowires 2 (FIG. 1B), because of action of the insulator-conversion promoting component 3 irradiated with light or heated. As preparation of the electrically insulating region 5 demands a period shorter than that by conventional methods, it is possible to produce a substrate carrying a larger-area transparent conductive film 1. Use applications of such a substrate carrying a transparent conductive film include, for example, touch panels, organic EL devices, liquid crystal displays, solar cells, photoelectric conversion elements, electromagnetic wave shields, electronic papers and the like.

### Example

Hereinafter, the present invention will be described more specifically with reference to Examples.

### (Metal Nanowire Dispersion A)

Ag nanowires (average diameter: 50 nm, average length: 5 μm) were prepared according to a known literature: Materials Chemistry and Physics, Vol. 114, pp 333-338, “Preparation of Ag nanorods with high yield by polyol process.” Then, 5 parts by mass of the Ag nanowires were dispersed in 95 parts by mass of water, to give a metal nanowire dispersion A having a solid matter content of 5.0 mass %.

### (Metal Nanowire Dispersion B)

The Ag nanowires above prepared by a known literature were dispersed in a plating solution containing Ag/ammonia complex prepared by adding silver nitrate to aqueous ammonia, and glucose as reducing agent was added thereto, to give Ag nanowires carrying Ag nanoparticles on the surface. Five parts by mass of the Ag nanowires were then dispersed in 95 parts by mass of water, to give a metal nanowire dispersion B having a solid matter content of 5.0 mass %.

### (Binder Material A)

4.8 parts by mass of a cellulosic resin (“SM”, solid matter content: 100 mass %, available from Shin-Etsu Chemical Co., Ltd.), 0.2 part by mass of carbon particles, 40 parts by mass of IPA, and 55 parts by mass of water were blended to give a binder material A having a solid matter content of 5 mass %.

### (Binder Material B)

9.41 parts by mass of a silicone resin (“MS51”, content as oxide: 51%, available from Mitsubishi Chemical Corporation), 0.2 part by mass of carbon particles, 85.39 parts by mass of IPA, and 5 parts by mass of 0.1N nitric acid were blended and mixed in a constant-temperature atmosphere at 25° C. additionally for 1 hour, to give a binder material B having a solid matter content of 5 mass %.

### (Binder Material C)

Four parts by mass of a cellulosic resin (“SM”, solid matter content: 100 mass %, available from Shin-Etsu Chemical Co., Ltd.), 3.33 parts by mass of ATO nanoparticles (IPA dispersion, solid matter content: 30%, available from CI Nano Tek Corporation), 37.67 parts by mass of IPA, and 55 parts by mass of water were blended, to give a binder material C having a solid matter content of 5 mass %. The ATO nanoparticles have a refractive index-adjusting function of increasing refractive index.

### (Binder Material D)

7.84 parts by mass of a silicone resin (“MS51”, content as oxide: 51%, available from Mitsubishi Chemical Corporation), 86.16 parts by mass of IPA, and 5 parts by mass of 0.1N nitric acid were blended and mixed in a constant-temperature atmosphere at 25° C. additionally for 1 hour, to give a binder material D having a solid matter content of 5 mass %.

### (Binder Material E)

Five parts by mass of a cellulosic resin (“SM”, solid matter content: 100 mass %, available from Shin-Etsu Chemical Co., Ltd.), 40 parts by mass of IPA, and 55 parts by mass of water were blended, to give a binder material E having a solid matter content of 5 mass %.

### (Binder Material F)

8.82 parts by mass of a silicone resin (“MS51”, content as oxide: 51%, available from Mitsubishi Chemical Corporation), 85.68 parts by mass of IPA, 0.5 part by mass of an aromatic sulfonium salt (“SI-80L”, available from Sanshin Chemical Industry Co., Ltd.), and 5 parts by mass of 0.1N nitric acid were blended and mixed in a constant-temperature atmosphere at 25° C. additionally for 1 hour, to give a binder material F having a solid matter content of 5 mass %.

### (Transparent Conductive Material A)

The metal nanowire dispersion A (2 parts by mass) and the binder material A (8 parts by mass) were blended to give a transparent conductive material A having a solid matter content of 5 mass %.

### (Transparent Conductive Material B)

The metal nanowire dispersion A (2 parts by mass) and the binder material B (8 parts by mass) were blended to give a transparent conductive material B having a solid matter content of 5 mass %.

### (Transparent Conductive Material C)

The metal nanowire dispersion A (2 parts by mass) and the binder material C (8 parts by mass) were blended to give a transparent conductive material C having a solid matter content of 5 mass %.

### (Transparent Conductive Material D)

The metal nanowire dispersion B (2 parts by mass) and the binder material D (8 parts by mass) were blended to give a transparent conductive material D having a solid matter content of 5 mass %.

### (Transparent Conductive Material E)

The metal nanowire dispersion B (2 parts by mass) and the binder material E (8 parts by mass) were blended to give a transparent conductive material E having a solid matter content of 5 mass %.

### (Transparent Conductive Material F)

The metal nanowire dispersion A (2 parts by mass) and the binder material F (8 parts by mass) were blended to give a transparent conductive material F having a solid matter content of 5 mass %.

### (Transparent Conductive Material G)

The metal nanowire dispersion A (2 parts by mass) and the binder material D (8 parts by mass) were blended to give a transparent conductive material G having a solid matter content of 5 mass %.

### (Transparent Conductive Material H)

The metal nanowire dispersion A (2 parts by mass) and the binder material E (8 parts by mass) were blended to give a transparent conductive material H having a solid matter content of 5 mass %.

The light absorption of the Ag nanowires and the carbon particles was determined by the following method. First, a first film and a second film were formed separately on the transparent substrate 9. The transparent substrate 9 used was a non-alkali glass plate (“No. 1737”, refractive index at a wavelength of 500 nm: 1.50 to 1.53, available from Corning Inc.). The first film was formed, as a first coating agent was applied on the transparent substrate 9, using a spin coater under the condition of 2000 rpm and 60 seconds. The first coating agent was prepared by blending the metal nanowire dispersion A (2 parts by mass), a cellulosic resin (“SM”, solid matter content: 100 mass %, available from Shin-Etsu Chemical Co., Ltd.) (5 parts by mass), IPA (40 parts by mass), and water (55 parts by mass). Meanwhile, the second film was formed, as a second coating agent was applied on the transparent substrate 9 using a spin coater under the condition of 2000 rpm and 60 seconds. The second coating agent was prepared by blending 4.8 parts by mass of a cellulosic resin (“SM”, solid matter content: 100 mass %, available from Shin-Etsu Chemical Co., Ltd.), 0.2 part by mass of carbon particles, 40 parts by mass of IPA, and 55 parts by mass of water. The total light transmittance of the first and second films was then determined, using a haze meter equipped with a light source D65. The result shows that the second film has a total light transmittance lower than that of the first film, indicating that carbon particles have a light absorption higher than that of Ag nanowires. Similar examination of the light absorption of Ag nanowires and ATO particles shows that ATO nanoparticles have a light absorption higher than that of Ag nanowires.

### Example 1

The transparent substrate 9 used was a non-alkali glass plate (“No. 1737”, refractive index at a wavelength of 500 nm: 1.50 to 1.53, available from Corning Inc.). The transparent conductive material A was applied on the surface of the transparent substrate by spin coating method and heated for drying and hardening under the condition of 100° C. and 5 minutes, to give a transparent conductive film having a film thickness of 100 nm. Then, to form an electrically insulating region, a light having an average energy density of 0.5 J/cm² was emitted to the left half of the transparent conductive film by means of a UV-YAG laser. Thus, a substrate carrying the transparent conductive film having an electrically conductive region in the right half of the transparent conductive film and an electrically insulating region in the left half thereof was prepared.

### Example 2

A transparent conductive film having a film thickness of 100 nm was prepared in a manner similar to Example 1, except that the transparent conductive material A was replaced with the transparent conductive material B. Then, an electrically insulating region was formed similarly to Example 1, to give a substrate carrying the transparent conductive film having an electrically conductive region in the right half of the transparent conductive film and an electrically insulating region in the left half thereof.

### Example 3

A transparent conductive film having a film thickness of 100 nm was prepared in a manner similar to Example 1, except that the transparent conductive material A was replaced with the transparent conductive material C. Then, an electrically insulating region was formed similarly to Example 1, to give a substrate carrying the transparent conductive film having an electrically conductive region in the right half of the transparent conductive film and an electrically insulating region in the left half thereof.

### Example 4

A transparent conductive film having a film thickness of 100 nm was prepared in a manner similar to Example 1, except that the transparent conductive material A was replaced with the transparent conductive material D. Then, an electrically insulating region was formed similarly to Example 1, to give a substrate carrying the transparent conductive film having an electrically conductive region in the right half of the transparent conductive film and an electrically insulating region in the left half thereof.

### Example 5

A transparent conductive film having a film thickness of 100 nm was prepared in a manner similar to Example 1, except that the transparent conductive material A was replaced with the transparent conductive material E. Then, an electrically insulating region was formed similarly to Example 1, to give a substrate carrying the transparent conductive film having an electrically conductive region in the right half of the transparent conductive film and an electrically insulating region in the left half thereof.

### Example 6

An electrically insulating region was formed in the left half of the transparent conductive film prepared in Example 2, as the right half of the transparent conductive film was covered with a mask and the left half was irradiated with light having an average energy density of 1 J/cm² by means of a xenon flash lamp, to give a substrate carrying the transparent conductive film having an electrically conductive region in the right half of the transparent conductive film and an electrically insulating region in the left half thereof.

### Example 7

An electrically insulating region was formed in the left half of the transparent conductive film prepared in Example 4, as the right half of the transparent conductive film was covered with a mask and the left half was irradiated with light having an average energy density of 1 J/cm² by means of a xenon flash lamp, to give a substrate carrying the transparent conductive film having an electrically conductive region in the right half of the transparent conductive film and an electrically insulating region in the left half thereof.

### Example 8

A transparent conductive film having a film thickness of 100 nm was prepared in a manner similar to Example 1, except that the transparent conductive material A was replaced with the transparent conductive material F. Then, an electrically insulating region was formed on the left half of the transparent conductive film, as the region was heated by means of a heat press under the condition of 200° C. and 30 seconds, to give a substrate carrying the transparent conductive film having an electrically conductive region in the right half of the transparent conductive film and an electrically insulating region in the left half thereof.

### Comparative Example 1

A substrate carrying the transparent conductive film was prepared in a manner similar to Example 1, except that the transparent conductive material A was replaced with the transparent conductive material G.

### Comparative Example 2

A substrate carrying the transparent conductive film was prepared in a manner similar to Example 1, except that the transparent conductive material A was replaced with the transparent conductive material H.

### Comparative Example 3

An electrically insulating region was formed on the left half of the transparent conductive film prepared in Comparative Example 1, as the right half of the transparent conductive film was cover with a mask and the left half thereof was irradiated with light having an average energy density 1 J/cm² by means of a xenon flash lamp, to give a substrate carrying the transparent conductive film having an electrically conductive region in the right half of the transparent conductive film and an electrically insulating region in the left half thereof.

The solid matter contents (part by mass) of the transparent conductive films of Examples 1 to 8 and Comparative Examples 1 to 3 are summarized in Table 1.

TABLE 1

| | | Metal | | binder materials A to F | | | | |
|---|---|---|---|---|---|---|---|---|
| | | nanowire | | | | | | Thermal |
| | | dispersion | | Cellulose | Silicone | Carbon | ATO | acid |
| | | A | B | resin | resin | particles | nanoparticles | generator |
| Example 1 | Transparent | 2 | 0 | 7.68 | 0 | 0.32 | 0 | 0 |
| | conductive | | | | | | | |
| | material A | | | | | | | |
| Example 2 | Transparent | 2 | 0 | 0 | 7.68 | 0.32 | 0 | 0 |
| | conductive | | | | | | | |
| | material B | | | | | | | |
| Example 3 | Transparent | 2 | 0 | 6.4 | 0 | 0 | 1.6 | 0 |
| | conductive | | | | | | | |
| | material C | | | | | | | |
| Example 4 | Transparent | 0 | 2 | 0 | 8 | 0 | 0 | 0 |
| | conductive | | | | | | | |
| | material D | | | | | | | |
| Example 5 | Transparent | 0 | 2 | 8 | 0 | 0 | 0 | 0 |
| | conductive | | | | | | | |
| | material E | | | | | | | |
| Example 6 | Transparent | 2 | 0 | 0 | 7.68 | 0.32 | 0 | 0 |
| | conductive | | | | | | | |
| | material B | | | | | | | |
| Example 7 | Transparent | 0 | 2 | 0 | 8 | 0 | 0 | 0 |
| | conductive | | | | | | | |
| | material D | | | | | | | |
| Example 8 | Transparent | 2 | 0 | 0 | 7.2 | 0 | 0 | 0.8 |
| | conductive | | | | | | | |
| | material F | | | | | | | |
| Comparative | Transparent | 2 | 0 | 0 | 8 | 0 | 0 | 0 |
| Example 1 | conductive | | | | | | | |
| | material G | | | | | | | |
| Comparative | Transparent | 2 | 0 | 8 | 0 | 0 | 0 | 0 |
| Example 2 | conductive | | | | | | | |
| | material H | | | | | | | |
| Comparative | Transparent | 2 | 0 | 0 | 8 | 0 | 0 | 0 |
| Example 3 | conductive | | | | | | | |
| | material G | | | | | | | |

### (Evaluation Method and Evaluation Results)

The surface resistance of the transparent conductive films in the substrates carrying a transparent conductive film of Examples 1 to 8 and Comparative Examples 1 to 3 was determined, using “Loresta” available from Mitsubishi Chemical Analytech Co., Ltd. The results are summarized in Table 2.

TABLE 2

| | Conductive region | Insulating region |
|---|---|---|
| | (Ω/□) | (Ω/□) |
| Example 1 | 20 | >10⁻⁷ |
| Example 2 | 20 | >10⁻⁷ |
| Example 3 | 35 | >10⁻⁷ |
| Example 4 | 15 | >10⁻⁷ |
| Example 5 | 15 | >10⁻⁷ |
| Example 6 | 25 | >10⁻⁷ |
| Example 7 | 15 | >10⁻⁷ |
| Example 8 | 20 | >10⁻⁷ |
| Comparative Example 1 | 25 | 50 |
| Comparative Example 2 | 25 | 40 |
| Comparative Example 3 | 25 | 30 |

As obvious from the results in Table 2, the electrically insulating regions of the transparent conductive films of Examples 1 to 8 have a surface resistance significantly increased, indicating that the surface resistance is increased when irradiated with light or heated. In contrast, the electrically insulating regions of the transparent conductive films of Comparative Examples 1 to 3 have a surface resistance not significantly increased, indicating that the surface resistance is not increased when irradiated with light or heated.

### REFERENCE SIGNS LIST

1 Transparent conductive film
2 Metal nanowire
3 Insulator-conversion promoting component
4 Electrically conductive region
5 Electrically insulating region
7 Metal nanoparticle
9 Transparent substrate
10 Resin component

1. A transparent conductive film, comprising:
an electrically conductive region; and
an electrically insulating region,
wherein:
the electrically conductive region contains a resin component, a metal nanowire, and an insulator-conversion promoting component;
the insulator-conversion promoting component is a nanoparticle having light absorption higher than that of the metal nanowire; and
the electrically insulating region is defined by a region which contains a resin component but not the metal nanowire or a region which contains a resin component and additionally a metal nanowire having an aspect ratio of smaller than that of the metal nanowire.

2. A transparent conductive film, comprising:
an electrically conductive region; and
an electrically insulating region,
wherein:
the electrically conductive region contains a resin component, a metal nanowire, and an insulator-conversion promoting component;
the insulator-conversion promoting component is a photochemical or thermal acid generator; and
the electrically insulating region is defined by a region which contains a resin component but not the metal nanowire or a region which contains a resin component and additionally a metal nanowire having an aspect ratio of smaller than that of the metal nanowire.

3. The transparent conductive film according to claim 1, wherein
the insulator-conversion promoting component is a component that decomposes the metal nanowire or reduces the aspect ratio of the metal nanowire when irradiated with light or heated.

4. A transparent conductive film, comprising:
an electrically conductive region; and
an electrically insulating region,
wherein:
the electrically conductive region contains a resin component, a metal nanowire, and an insulator-conversion promoting component;
the insulator-conversion promoting component is defined to decompose the metal nanowire or reduce the aspect ratio of the metal nanowire when irradiated with light or heated; and
the electrically insulating region is defined by a region which contains a resin component but not the metal nanowire or a region which contains a resin component and additionally a metal nanowire having an aspect ratio of smaller than that of the metal nanowire.

5. The transparent conductive film according to claim 1, wherein
the insulator-conversion promoting component is a metal nanoparticle.

6. The transparent conductive film according to claim 1, wherein
the insulator-conversion promoting component is carbon.

7. The transparent conductive film according to claim 1, wherein
the insulator-conversion promoting component is a metal nanoparticle deposited on a surface of the metal nanowire through electroless plating.

8. The transparent conductive film according to claim 5, wherein
the metal nanoparticle is an Ag nanoparticle.

9. The transparent conductive film according to claim 1, wherein
the insulator-conversion promoting component has a refractive index-adjusting function of increasing or decreasing refractive indices of the electrically conductive region and the electrically insulating region.

10. The transparent conductive film according to claim 1, wherein
the electrically conductive region and the electrically insulating region contain refractive index-adjusting components increasing or decreasing refractive indices of the electrically conductive region and the electrically insulating region, respectively.

11. The transparent conductive film according to claim 1, wherein
the metal nanowire is an Ag nanowire.

12. The transparent conductive film according to claim 1, wherein
the metal nanowire has an average diameter of 100 nm or less.

13. A substrate carrying a transparent conductive film, prepared by forming the transparent conductive film according to claim 1 on a transparent substrate.

14. A method for producing a substrate carrying a transparent conductive film, comprising the steps of:
forming a transparent conductive film on a transparent substrate, the transparent conductive film being constituted by an electrically conductive region containing a resin component, a metal nanowire, and an insulator-conversion promoting component, and the insulator-conversion promoting component being defined by a nanoparticle having light absorption higher than that of the metal nanowire; and
forming an electrically insulating region by irradiating a region to be insulated of the transparent conductive film with light.

15. A method for producing a substrate carrying a transparent conductive film, comprising the steps of:
forming a transparent conductive film on a transparent substrate, the transparent conductive film being constituted by an electrically conductive region containing a resin component, a metal nanowire and an insulator-conversion promoting component, and the insulator-conversion promoting component being defined by a photochemical or thermal acid generator; and
forming an electrically insulating region by irradiating with light or heating a region to be insulated of the transparent conductive film.

16. The transparent conductive film according to claim 7, wherein
the metal nanoparticle is an Ag nanoparticle.

17. The transparent conductive film according to claim 2, wherein
the insulator-conversion promoting component has a refractive index-adjusting function of increasing or decreasing refractive indices of the electrically conductive region and the electrically insulating region.

18. The transparent conductive film according to claim 4, wherein
the insulator-conversion promoting component has a refractive index-adjusting function of increasing or decreasing refractive indices of the electrically conductive region and the electrically insulating region.
